(19) United States
(12) Patent Application Publication
(10) Pub. No.: US 2012/0018746 A1
(43) Pub. Date: Jan. 26, 2012

(54) ARRAY-TYPE LED DEVICE

(76) Inventor: Min-Hsun HSIEH, (US)

(21) Appl. No.: 13/186,843

(22) Filed: Jul. 20, 2011

(30) Foreign Application Priority Data
Jul. 20, 2010 (TW) 099124058

(51) Int. Cl. H01L 33/62

(52) U.S. Cl. 257/88; 257/E33.066

(57) ABSTRACT

An array-type LED device includes a substrate; and a plurality of light-emitting elements located on the substrate, wherein each of the plurality of light-emitting elements includes a first semiconductor layer having a first region and a second region; and a second semiconductor layer with an oblique angle located on the second region. The light-emitting element further includes a first electrical-contact region located on the first region, and a second electrical-contact region located on the second semiconductor layer, wherein the lateral resistance of the second semiconductor layer is larger than that of the first semiconductor layer.

### TECHNICAL FIELD

The application relates to a photoelectric device, and more particularly, to an array-type LED device having a semiconductor layer with an oblique angle.

### REFERENCE TO RELATED APPLICATION

This application claims the right of priority based on Taiwan application Serial No. 099124058, filed on Jul. 20, 2010, and the content of which is hereby incorporated by reference in its entirety.

### DESCRIPTION OF BACKGROUND ART

The light-emitting diode (LED) is a solid state semiconductor device, which at least comprises a p-n junction formed between the p-type and the n-type semiconductor layers. When a certain degree of bias voltage is supplied through the p-n junction, the holes of the p-type semiconductor layer combine with the electrons of the n-type semiconductor layer, and the light is emitted. The region where the light is emitted is called the light-emitting region.

As shown in FIG. 8, the conventional LED 8 comprises a rectangular n-type semiconductor layer 81 and a rectangular p-type semiconductor layer 82. An n-type pad 83 is positioned on the n-type semiconductor layer 81, and a p-type pad 84 is positioned on the p-type semiconductor layer 82. When a bias voltage is supplied into the n-type pad 83 and the p-type pad 84, the electric current flows from the p-type pad 84 to the n-type pad 83 along the path c. However, the lateral resistance of the p-type semiconductor layer 82 is higher than the lateral resistance of the n-type semiconductor layer 81, and the diffusion rate of the electric current is worse in the p-type semiconductor layer, so the probability of the electric current flowing through the portion region 821 positioned near the p-type pad 84 of the rectangular p-type semiconductor layer 82 is lower. Thus, the light emitting probability of the region under the portion region 821 is also lower.

The characteristics of LED are small size, high luminous efficiency, long life time, quickly response, high reliability and good chromaticity. Now, LED has been widely required in as applications like the electronic apparatus, automobiles, displays and the traffic signals. With the advent of the full-color LED, LED has gradually replaced the conventional lighting devices such as the fluorescent bulb and the incandescent bulb.

The above-described light-emitting diode is further processed into a light-emitting device by connecting the substrate and the board with the soldering or the plastic. Otherwise, the board further comprises at least one electric circuit for electrically connecting the electrode of the light emitting device by a conductive structure such as metal wires.

### SUMMARY OF THE APPLICATION

An array-type LED device of an embodiment comprises a substrate, and a plurality of light-emitting elements located on the substrate. A light-emitting element comprises a first semiconductor layer comprising a first side, a second side, a third side and a fourth side, wherein the second side faces the first side and is shorter than the first side, the third side and the fourth side face each another, the two ends of the first side respectively connect to one end of the third side and one end of the fourth side, the two ends of the second side respectively connect to another ends of the third side and the fourth side, and wherein the second side forms an oblique angle with at least one of the third side and the fourth side; a second semiconductor layer formed on the first semiconductor layer; a first electrical-contact region formed on the first semiconductor layer and electrically connected to the first semiconductor layer; and a second electrical-contact region formed on the second semiconductor layer and electrically connected to the second semiconductor layer, and wherein the first electrical-contact region and the second electrical-contact region are formed on the same side of the substrate.

### BRIEF DESCRIPTION OF THE DRAWINGS

FIG. 1 illustrates a cross-sectional diagram of the first embodiment according to the application;

FIG. 2A illustrates a top view of the second embodiment according to the application;

FIG. 2B illustrates a top view of the third embodiment according to the application;

FIG. 3A illustrates a top view of the fourth embodiment according to the application;

FIG. 3B illustrates a top view of the fifth embodiment according to the application;

FIG. 4A illustrates a top view of the sixth embodiment according to the application;

FIG. 4B illustrates a top view of the seventh embodiment according to the application;

FIG. 5A illustrates a top view of the eighth embodiment according to the application;

FIG. 5B illustrates a top view of the ninth embodiment according to the application;

FIG. 6 illustrates the diagram of a light generation device according to the embodiment of the application;

FIG. 7 illustrates the diagram of a back light module according to the embodiment of the application; and

FIG. 8 illustrates the diagram of the conventional LED.

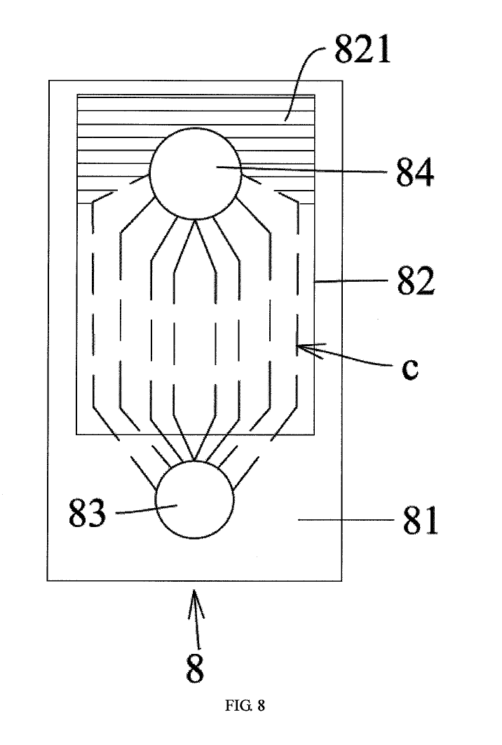

### DETAILED DESCRIPTION OF PREFERRED EMBODIMENTS

The embodiment of the application is illustrated in detail, and is plotted in the drawings. The same or the similar part is illustrated in the drawings and the specification with the same number.

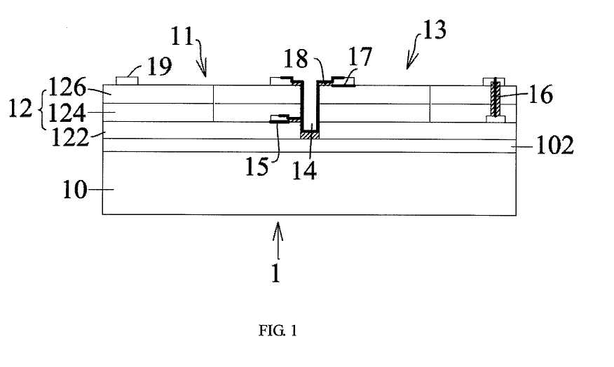

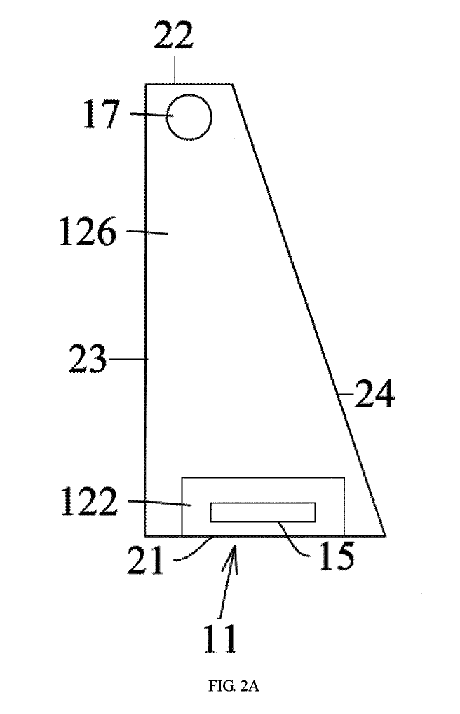

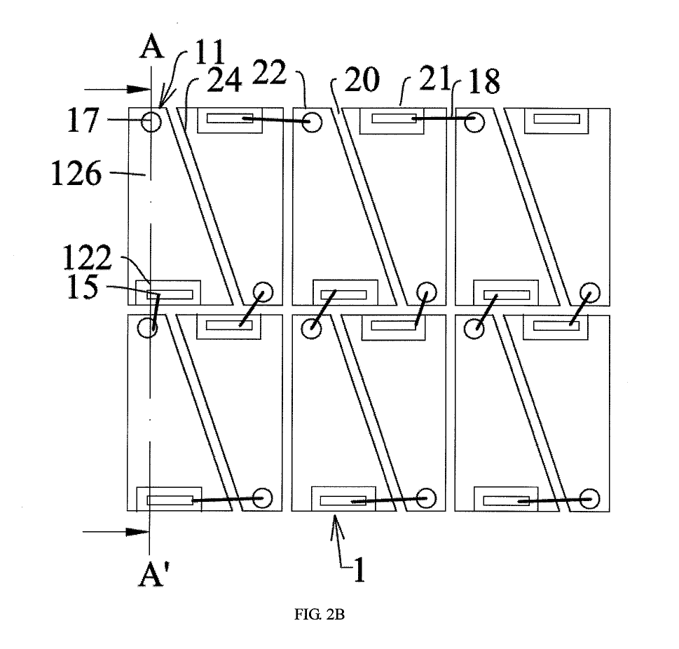

FIG. 1 illustrates a cross-sectional diagram taken along line A-A′ in FIG. 2B. As shown in FIG. 1, an array-type LED device 1 of the first embodiment comprises a substrate 10 and a light-emitting stack 12 formed on the substrate 10, wherein the light-emitting stack 12 comprises a first semiconductor layer 122, an active layer 124, and a second semiconductor layer 126, wherein the area of the second semiconductor layer 126 is smaller than the area of the first semiconductor layer 122, and the area of the active layer 124 is about the same with that of the second semiconductor layer 126. The second semiconductor layer 126 can be a p-type semiconductor layer or an n-type semiconductor layer, and the polarity of the second semiconductor layer 126 is different from the first semiconductor layer 122. The active layer 124 is formed between the first semiconductor layer 122 and the second semiconductor layer 126. The array-type LED device 1 comprises a first trench 14, wherein the first trench 14 separates the light-emitting stack 12 into a first light-emitting element 11 and a second light-emitting element 13. The first semiconductor layer 122 comprises a first electrical-contact region 15 formed on the top surface of the first semiconductor layer 122, and the second semiconductor layer 126 comprises a second electrical-contact region 17 formed on the top surface of the second semiconductor layer 126. Following, an insulating layer 16 is formed on the surfaces of the first trench 14, the first light-emitting element 11 and the second light-emitting element 13, but the first electrical-contact region 15 and the second electrical-contact region 17 are exposed. The formation method of the insulating layer 16 includes, but not limited to, electron beam evaporation (E-Gun), sputtering, or plasma enhanced chemical vapor deposition (PECVD). An electrically connecting wire 18 is formed on the insulating layer 16 for electrically connecting the first electrical-contact region 15 of the first light-emitting element 11 and the second electrical-contact region 17 of the second light-emitting element 13, wherein the formation method of the electrically connecting wire 18 includes evaporation, chemical plating or electroplating such as physical vapor deposition (PVD), chemical vapor deposition (CVD), metal organic chemical vapor deposition (MOCVD), or electron beam evaporation (E-Gun). The light-emitting elements are electrically connected by the electrically connecting wire 18 through the electrical-contact regions. Or, the light-emitting elements are electrically connected by the electrically connecting wire 18 through the electrode or the pad 19 formed on the electrical-contact region. The configuration of electrical connection can be in series or parallel. The array-type LED device 1 optionally comprises a connecting layer 102 formed between the substrate 10 and the light-emitting stack 12. The light-emitting element can be driven by AC power or DC power.

The substrate 10 can be used to form and/or support the light-emitting stack 12. The material of the substrate comprises transparent material such as sapphire, diamond, or glass; electrical insulation material such as quartz, zinc oxide (ZnO), aluminum nitride (AlN); polymer material such as acryl. The material of the substrate can also comprise high heat dissipation material such as diamond like carbon (DLC), graphite, silicon carbide (SiC), or carbon fiber; reflective material such as copper (Cu), aluminum (Al), molybdenum (Mo), copper-tin (Cu-Sn), copper-zinc (Cu-Zn), copper-cadmium (Cu-Cd), nickel-tin (Ni-Sn), nickel-cobalt (Ni-Co), or Au alloy; composite material such as metal matrix composite (MMC), ceramic matrix composite (CMC), or polymer matrix composite (PMC); semiconductor material such as silicon (Si), phosphorus iodine (IP), zinc selenide (ZnSe), gallium arsenide (GaAs), gallium phosphide (GaP), gallium nitride (GaN), gallium arsenide phosphate (GaAsP), indium phosphide (InP), lithium dioxogallate (LiGaO₂) or lithium aluminum oxide (LiAlO₂), wherein the material used to form the light-emitting stack 12 comprises sapphire, gallium arsenide (GaAs), silicon carbide (SiC), or gallium nitride (GaN).

The material of the light-emitting stack 12 comprises more than one element selecting from a group consisting of gallium (Ga), aluminum (Al), indium (In), phosphor (P), nitrogen (N), zinc (Zn), cadmium (Cd), and selenium (Se). The material of the connecting layer 102 comprises conductive material such as indium tin oxide (ITO), indium oxide (InO), tin oxide (SnO), cadmium tin oxide (CTO), antimony tin oxide (ATO), aluminum zinc oxide (AZO), zinc tin oxide (ZTO), or indium zinc oxide (IZO); semiconductor material such as silicon, aluminum gallium arsenide (AlGaAs), gallium nitride (GaN), gallium phosphide (GaP), gallium arsenide (GaAs), or gallium arsenide phosphate (GaAsP); dielectric material such as magnesium oxide (MgO), zinc oxide (ZnO), aluminum oxide (Al₂O₃), tantalum oxide (Ta₂O₅), silicon oxide (SiOₓ), titanium oxide (TiO₂), silicon nitride (SiNₓ), or spin on glass (SOG); non-conductive material such as glass or organic polymers like polyimide, benzocyclobutene (BCB), prefluorocyclobutane (PFCB), polymethylmethacrylate (PMMA), polyethylene terephthalate (PET), polycarbonate (PC), polyetherimide, fluorocarbon polymer, cyclic olefin copolymers (COC), Su8, epoxy, or acrylic resin; or diamond like carbon (DLC). When the material of the connecting layer 102 is conductive, the first trench 14 extends downwards to expose a portion of the substrate 10.

As shown in FIG. 2A, the second embodiment is illustrated by the first light-emitting element 11. The top view of the first light-emitting element 11 is a quadrilateral with at least two unequal sides. The first semiconductor layer 122 comprises a first side 21, a second side 22, a third side 23 and a fourth side 24, wherein the second side 22 faces the first side 21 and is shorter than the first side 21, the third side 23 and the fourth side 24 face each another, the two ends of the first side 21 respectively connect to one end of the third side 23 and one end of the fourth side 24, the two ends of the second side 22 respectively connect to another ends of the third side 23 and the fourth side 24, wherein the second side 22 forms an oblique angle with at least one of the third side 23 and the fourth side 24, and wherein the second side 22 can also be the shortest one of the four sides, or is substantially an arc. In addition, the first side 21 and the second side 22 can be the two shortest sides of the four sides; the lengths of the first side 21, the third side 23 and the fourth side 24 can be the same or different. In the embodiment, the lateral resistance of the second semiconductor layer 126 is larger than the lateral resistance of the first semiconductor layer 122. The second electrical-contact region 17 is formed on the second semiconductor layer 126 and electrically connected to the second semiconductor layer 126, and is preferred to be formed near the second side 22 and further preferred to include part of the second side 22. The first electrical-contact region 15 is formed on the first semiconductor layer 122 and electrically connected to the first semiconductor layer 122, and is preferred to be formed near the first side 21 and further preferred to include part of the first side 21. The second semiconductor layer 126 of the second embodiment can be a p-type semiconductor layer or an n-type semiconductor layer, and the p-type semiconductor layer is preferable. Embodiments are not limited to quadrilateral, but can also be polygon which has more than four sides. Otherwise, the first light-emitting element 11 optionally comprises a connecting layer (not shown in the drawings) formed between the substrate (not shown in the drawings) and the first semiconductor layer 122.

As shown in FIG. 2B, the array-type LED device 1 of the third embodiment comprises a plurality of first light-emitting elements 11, wherein the plurality of first light-emitting elements 11 is electrically connected to one another. In the embodiment, the plurality of first light-emitting elements 11 is connected in series. A second trench 20 is formed to separate the plurality of light-emitting elements. The first side 21 of each light-emitting element is positioned near the second side 22 of the adjacent light-emitting element, and/or the fourth side 24 of each light-emitting element is approximately parallel to the fourth side 24 of the adjacent light-emitting element. Otherwise, the plurality of light-emitting elements of the array-type LED device 1 can also be connected to one another in parallel (not shown in the drawings), and can also be driven by AC power or DC power.

Since the lateral resistance of the second semiconductor layer 126 is larger than the lateral resistance of the first semiconductor layer 122, the diffusion rate of electric current in the second semiconductor layer 126 is slower than the one in the first semiconductor layer 122. If the second electrical-contact region 17 is formed near the second side 22, and the second side 22 is shorter than the first side 21, then the area of the second semiconductor layer 126 near the second side 22 is smaller than the one near the first side 21. Thus, the electric current fully spreads around the second electrical-contact region 17, and the current spreading of the electric current in the second semiconductor layer 126 is more uniform. The second semiconductor layer 126 comprises part of the first side 21, and the areas of the active layer 124 and the second semiconductor layer 126 are approximately the same. The electric current spreading uniformly in the second semiconductor layer 126 approximately passes through the whole area of the active layer 124, so the effective light emitting area of the active layer 124 is increased, and the luminous efficiency of the light-emitting element is also improved.

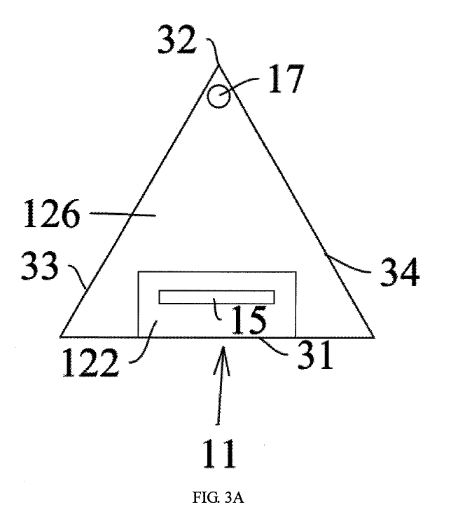

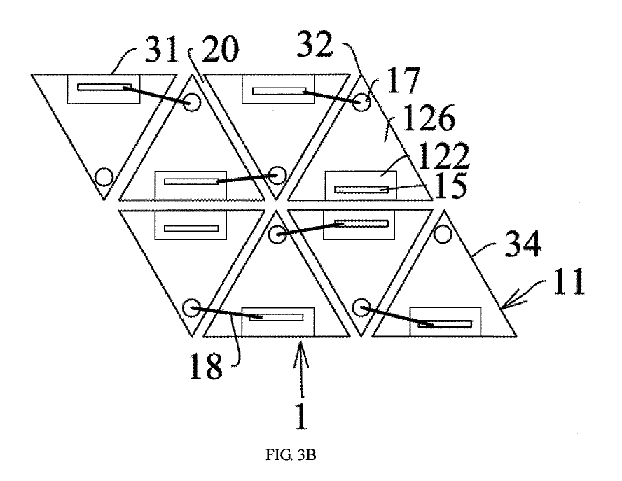

As shown in FIG. 3A, the fourth embodiment is approximately similar to the second embodiment, and one difference is that the top view of the first light-emitting element 11 of the fourth embodiment is a triangle. The first light-emitting element 11 of the fourth embodiment comprises a first side 31, a second side 32, a third side 33 and a fourth side 34, wherein the length of the second side 32 is close or equal to zero, or the second side 32 is a point at where the third side 33 and the fourth side 34 meet. Therefore, the top view of the second semiconductor layer 126 is a triangle, and the second side 32 is an apex of the triangle. The first semiconductor layer 122 comprises a first side 31, a second side 32, a third side 33, and a fourth side 34. In the embodiment, the lateral resistance of the second semiconductor layer 126 is larger than the lateral resistance of the first semiconductor layer 122. The second electrical-contact region 17 is formed on the second semiconductor layer 126 and electrically connected to the second semiconductor layer 126, and is preferred to be formed near the second side 32 and further preferred to include part of the second side 32. The first electrical-contact region 15 is formed on the first semiconductor layer 122 and electrically connected to the first semiconductor layer 122, and is preferred to be formed near the first side 31 and further preferred to include part of the first side 31. The second semiconductor layer 126 of the fourth embodiment can be a p-type semiconductor layer or an n-type semiconductor layer, and the p-type semiconductor layer is preferable. Otherwise, the first light-emitting element 11 optionally comprises a connecting layer (not shown in the drawings) formed between the substrate (not shown in the drawings) and the first semiconductor layer 122.

As shown in FIG. 3B, the array-type LED device 1 of the fifth embodiment comprises a plurality of first light-emitting elements 11, wherein the plurality of first light-emitting elements 11 is electrically connected to one another. In the embodiment, the plurality of first light-emitting elements 11 is connected in series. A second trench 20 is formed to separate the plurality of light-emitting elements. The first side 31 of each light-emitting element is positioned near the second side 32 of the adjacent light-emitting element, and/or the fourth side 34 of each light-emitting element is approximately parallel to the fourth side 34 of the adjacent light-emitting element. Otherwise, the plurality of the light-emitting elements of the array-type LED device 1 can also be connected to one another in parallel (not shown in the drawings), and can also be driven by AC power or DC power.

Since the second electrical-contact region 17 is formed near the second side 32, if the length of the second side 32 is close or equal to zero, then the area of the second semiconductor layer 126 near the second side 32 is smaller than the one near the first side 31. Thus, the electric current fully spreads around the second electrical-contact region 17, and the current spreading of the electric current in the second semiconductor layer 126 is more uniform. The second semiconductor layer 126 comprises part of the first side 31, and the areas of the active layer 124 and the second semiconductor layer 126 are approximately the same. The electric current spreading uniformly in the second semiconductor layer 126 approximately passes through the whole area of the active layer 124, so the effective light emitting area of the active layer 124 is increased, and the luminous efficiency of the light-emitting element is also improved.

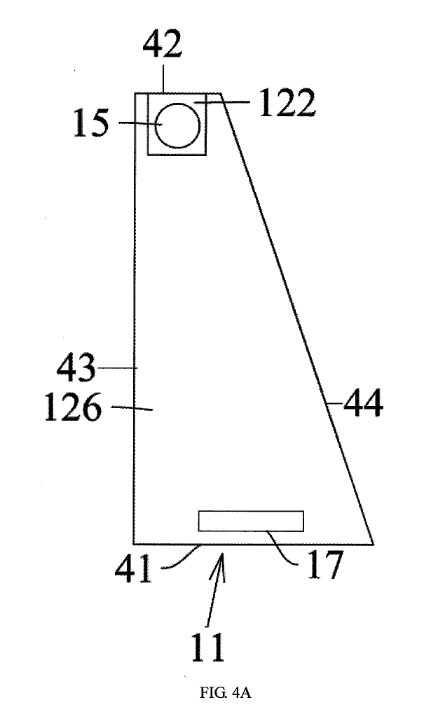

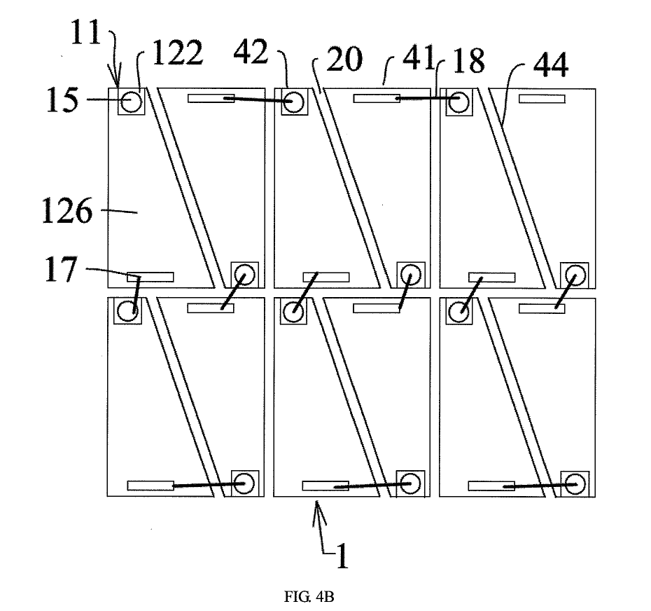

As shown in FIG. 4A, the sixth embodiment is illustrated by the first light-emitting element 11. The top view of the first light-emitting element 11 is a quadrilateral with at least two unequal sides. The first semiconductor layer 122 comprises a first side 41, a second side 42, a third side 43, and a fourth side 44, wherein the second side 42 faces the first side 41 and is shorter than the first side 41, the third side 43 and the fourth side 44 face each another, the two ends of the first side 41 respectively connect to one end of the third side 43 and one end of the fourth side 44, the two ends of the second side 42 respectively connect to another ends of the third side 43 and the fourth side 44, wherein the second side 42 forms an oblique angle with at least one of the third side 43 and the fourth side 44, and wherein the second side 42 can also be the shortest one of the four sides, or is substantially an arc. In addition, the first side 41 and the second side 42 can be the two shortest sides of the four sides; the lengths of the first side 41, the third side 43 and the fourth side 44 can be the same or different. In the embodiment, the lateral resistance of the first semiconductor layer 122 is larger than the lateral resistance of the second semiconductor layer 126. The first electrical-contact region 15 is formed on the first semiconductor layer 122 and electrically connected to the first semiconductor layer 122, and is preferred to be formed near the second side 42 and further preferred to include part of the second side 42. The second electrical-contact region 17 is formed on the second semiconductor layer 126 and electrically connected to the second semiconductor layer 126, and is preferred to be formed near the first side 41 and further preferred to include part of the first side 41. The first semiconductor layer 122 of the sixth embodiment can be a p-type semiconductor layer or an n-type semiconductor layer, and the p-type semiconductor layer is preferable. Embodiments are not limited to quadrilateral, but can also be polygon which has more than four sides. Otherwise, the first light-emitting element 11 optionally comprises a connecting layer (not shown in the drawings) formed between the substrate (not shown in the drawings) and the first semiconductor layer 122.

As shown in FIG. 4B, the array-type LED device 1 of the seventh embodiment comprises a plurality of first light-emitting elements 11, wherein the plurality of first light-emitting elements 11 is electrically connected to one another. In the embodiment, the plurality of light-emitting elements is connected in series. A second trench 20 is formed to separate the plurality of light-emitting elements. The first side 41 of each light-emitting element is positioned near the second side 42 of the adjacent light-emitting element, and/or the fourth side 44 of each light-emitting element is approximately parallel to the fourth side 44 of the adjacent light-emitting element. Otherwise, the plurality of the light-emitting elements of the array-type LED device 1 can also be connected to one another in parallel, and can also be driven by AC power or DC power.

Since the lateral resistance of the first semiconductor layer 122 is larger than the lateral resistance of the second semiconductor layer 126, the diffusion rate of electric current in the first semiconductor layer 122 is slower than the one in the second semiconductor layer 126. If the first electrical-contact region 15 is formed near the second side 42, and the second side 42 is shorter than the first side 41, then the area of the first semiconductor layer 122 near the second side 42 is smaller than the one near the first side 41. Thus, the electric current fully spreads around the first electrical-contact region 15, and the current spreading of the electric current in the first semiconductor layer 122 is more uniform. The electric current spreading uniformly in the first semiconductor layer 122 approximately passes through the whole area of the active layer 124, so the effective light emitting area of the active layer 124 is increased, and the luminous efficiency of the light-emitting element is also improved.

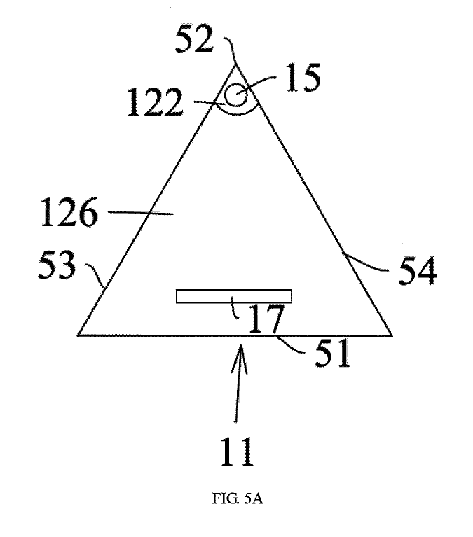

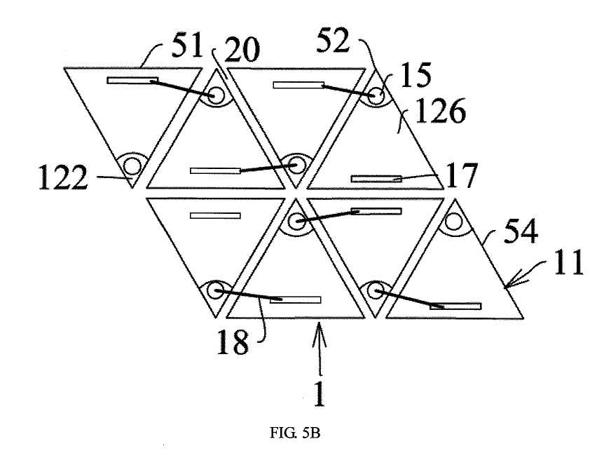

As shown in FIG. 5A, the eighth embodiment is approximately similar to the sixth embodiment, and one difference is that the top view of the first light-emitting element 11 of the eighth embodiment is a triangle. The first light-emitting element 11 of the eighth embodiment comprises a first side 51, a second side 52, a third side 53 and a fourth side 54, wherein the length of the second side 52 is close or equal to zero, or the second side 52 is a point at where the third side 53 and the fourth side 54 meet, so the second side 52 is an apex of the triangle. The first semiconductor layer 122 comprises a first side 51, a second side 52, a third side 53 and a fourth side 54. In the embodiment, the lateral resistance of the first semiconductor layer 122 is larger than the lateral resistance of the second semiconductor layer 126. The first electrical-contact region 15 is formed on the first semiconductor layer 122 and electrically connected to the first semiconductor layer 122, and is preferred to be formed near the second side 52 and further preferred to include part of the second side 52. The second electrical-contact region 17 is formed on the second semiconductor layer 126 and electrically connected to the second semiconductor layer 126, and is preferred to be formed near the first side 51 and further preferred to include part of the first side 51. The first semiconductor layer 122 of the eighth embodiment can be a p-type semiconductor layer or an n-type semiconductor layer, and the p-type semiconductor layer is preferable. Otherwise, the light-emitting element 11 optionally comprises a connecting layer (not shown in the drawings) formed between the substrate (not shown in the drawings) and the first semiconductor layer 122.

As shown in FIG. 5B, the array-type LED device 1 of the ninth embodiment comprises a plurality of first light-emitting elements 11, wherein the plurality of first light-emitting elements 11 is electrically connected to one another. In the embodiment, the plurality of light-emitting elements is connected in series. A second trench 20 is formed to separate the plurality of light-emitting elements. The first side 51 of each light-emitting element is positioned near the second side 52 of the adjacent light-emitting element, and/or the fourth side 54 of each light-emitting element is approximately parallel to the fourth side 54 of the adjacent light-emitting element. Otherwise, the plurality of the light-emitting elements of the array-type LED device 1 can also be connected to one another in parallel (not shown in the drawings), and can also be driven by AC power or DC power.

Since the first electrical-contact region 15 is formed near the second side 52, if the length of the second side 52 is close or equal to zero, the area of the first semiconductor layer 122 near the second side 52 is smaller than the one near the first side 51. Thus, the electric current fully spreads around the first electrical-contact region 15, and the current spreading of the electric current in the first semiconductor layer 122 is more uniform. The electric current spreading uniformly in the first semiconductor layer 122 approximately passes through the whole area of the active layer 124, so the effective light emitting area of the active layer 124 is increased, and the luminous efficiency of the light-emitting element is also improved.

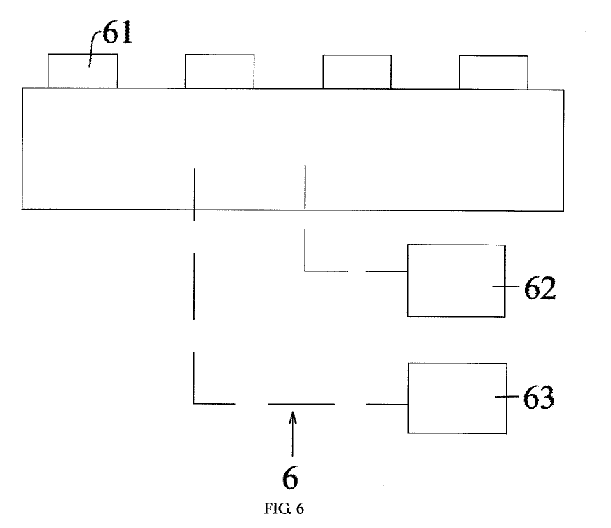

FIG. 6 illustrates the diagram of a light generation device. A light generation device 6 comprises the light-emitting element or the array-type LED device illustrated in any embodiment of the application. The light generation device 6 may be the lighting such as street lamp, headlights or indoor lighting, may also be traffic signal, or the backlight of the flat panel display backlight module. The light generation device 6 comprises a light source 61 including the above-described light-emitting element or the array-type LED device, a power supply system 62 providing an electric current for the light source 61, and a control element 63 controlling the power supply system 62.

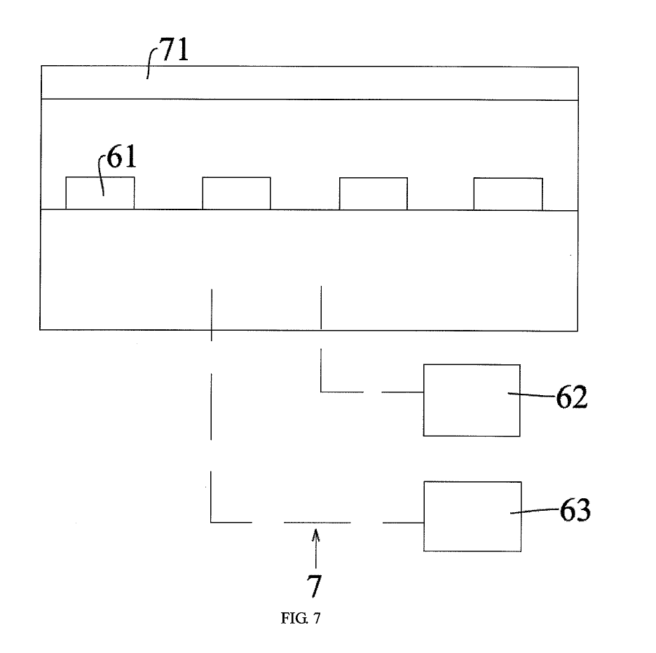

FIG. 7 illustrates the cross-sectional diagram of a backlight module. A backlight module 7 comprises the light generation device 6 described in the above embodiment, and an optical element 71. The optical element 71 deals with the light emitted from the light generation device 6 to apply the light to the flat panel display, such as scattering the light emitted from the light generation device 6.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A array-type LED device, comprising:
a plurality of light-emitting elements, wherein any one of the light-emitting element comprises:
a first semiconductor layer comprising a first side, and a second side facing and away from the first side;
a second semiconductor layer formed on the first semiconductor layer;
a first electrical-contact region formed on the first semiconductor layer and near the first side; and
a second electrical-contact region formed on the second semiconductor layer and near the second side, wherein the lateral resistance of the second semiconductor layer is larger than the lateral resistance of the first semiconductor layer, and the length of the second side is shorter than that of the first side.

2. The array-type LED device as claimed in claim 1, wherein the second semiconductor layer is a p-type semiconductor layer.

3. The array-type LED device as claimed in claim 1, further comprising a substrate for supporting the plurality of light-emitting elements.

4. The array-type LED device as claimed in claim 1, wherein the second side is substantially an arc, and/or the length of the second side is close or equal to zero.

5. The array-type LED device as claimed in claim 1, wherein the light-emitting elements are connected to one another in series or in parallel by the first electrical-contact region and the second electrical-contact region.

6. The array-type LED device as claimed in claim 1, wherein the light-emitting element further comprises an active layer formed between the first semiconductor layer and the second semiconductor layer, and/or an electrode or a pad formed on the first electrical-contact region and/or the second electrical-contact region.

7. The array-type LED device as claimed in claim 1, wherein the first side of each light-emitting element is positioned near the second side of the adjacent light-emitting element.

8. The array-type LED device as claimed in claim 1, wherein the top view of the light-emitting element is a quadrilateral or a triangle.

9. A array-type LED device, comprising:
a plurality of light-emitting elements, wherein any one of the light-emitting element comprises:
a first semiconductor layer comprising a first side, and a second side facing and away from the first side;
a second semiconductor layer formed on the first semiconductor layer;
a first electrical-contact region formed on the first semiconductor layer and near the second side; and
a second electrical-contact region formed on the second semiconductor layer and near the first side, wherein the lateral resistance of the first semiconductor layer is larger than the lateral resistance of the second semiconductor layer, and the length of the second side is shorter than that of the first side.

10. The array-type LED device as claimed in claim 9, further comprising a substrate for supporting the plurality of light-emitting elements.

11. The array-type LED device as claimed in claim 9, further comprising a connecting layer formed between the substrate and the plurality of light-emitting elements.

12. The array-type LED device as claimed in claim 9, wherein the second side is substantially an arc, and/or the length of the second side is close or equal to zero.

13. The array-type LED device as claimed in claim 9, wherein the light-emitting elements are connected to one another in series or in parallel by the first electrical-contact region and the second electrical-contact region.

14. The array-type LED device as claimed in claim 9, wherein the second semiconductor layer is an n-type semiconductor layer.

15. The array-type LED device as claimed in claim 9, wherein the light-emitting element further comprises an active layer formed between the first semiconductor layer and the second semiconductor layer, and/or an electrode or a pad formed on the first electrical-contact region and/or the second electrical-contact region.

16. The array-type LED device as claimed in claim 9, wherein the first side of each light-emitting element is positioned near the second side of the adjacent light-emitting element.

17. The array-type LED device as claimed in claim 9, wherein the top view of the light-emitting element is a quadrilateral or a triangle.

18. An array-type LED device, comprising:
a plurality of light-emitting elements, comprising:
a first light-emitting element comprising a first semiconductor layer including the first side, the second side facing and away from the first side, and a third side connected to the first side and the second side, wherein at least one of the first side and the second side is connected to the third side with an oblique angle;
a second light-emitting element comprising a second semiconductor layer including a fourth side, a fifth side facing and away from the first side, and a sixth side connected to the first side and the second side, wherein at least one of the fourth side and the fifth side is connected to the sixth side with an oblique angle, and wherein the third side is parallel and adjacent to the fifth side; and
an electrically connecting structure for electrically connecting the first light-emitting element and the second light-emitting element.

19. The array-type LED device as claimed in claim 18, wherein the lateral resistance of the first semiconductor layer and the lateral resistance of the second semiconductor layer are not equal.

20. The array-type LED device as claimed in claim 18, wherein the second side is smaller than the first side, the fifth side is smaller than the fourth side, and the second side and the fifth side are respectively positioned on two sides of the third side and the sixth side.

21. The array-type LED device as claimed in claim 20, wherein the second side and the fifth side are close or equal to zero.
